(19) United States
(12) Patent Application Publication
(10) Pub. No.: US 2025/0336868 A1
(43) Pub. Date: Oct. 30, 2025

(54) ELECTRONIC STRUCTURE INCLUDING AN INTERCONNECTION FILM

(71) Applicant: COMMISSARIAT À L’ENERGIE ATOMIQUE ET AUX ENERGIES ALTERNATIVES, PARIS (FR)

(72) Inventors: Jean-Charles SOURIAU, GRENOBLE CEDEX 09 (FR); Julia DE GIROLAMO, GRENOBLE CEDEX 09 (FR); Adeline FOURNIER, GRENOBLE CEDEX 09 (FR)

(21) Appl. No.: 18/685,807

(22) PCT Filed: Aug. 19, 2022
(86) PCT No.: PCT/EP2022/073139

§ 371 Date: Jul. 3, 2025

(30) Foreign Application Priority Data
Aug. 23, 2021 (FR) FR2108819

(51) Int. Cl. H01L 23/00

(52) U.S. Cl. CPC H01L 24/13; H01L 24/11; H01L 24/16; H01L 24/27; H01L 24/29; H01L 24/32; H01L 24/73; H01L 24/81; H01L 24/83; H01L 24/92; H01L 2224/11003; H01L 2224/11452; H01L 2224/13017; H01L 2224/13019; H01L 2224/13193; H01L 2224/16227; H01L 2224/16238; H01L 2224/27003; H01L 2224/27312; H01L 2224/278; H01L 2224/29017; H01L 2224/29019; H01L 2224/29191; H01L 2224/32227; H01L 2224/73104; H01L 2224/81005; H01L 2224/81192; H01L 2224/81201; H01L 2224/81895; H01L 2224/83005; H01L 2224/83201; H01L 2224/83896; H01L 2224/9221

(57) ABSTRACT

An electronic structure includes a substrate; an electronic component; and an interconnection film disposed between the substrate and the electronic component, electrically and mechanically connecting the electronic component to the substrate; the interconnection film including a first face, a second face opposite to the first face, an electrically conductive zone extending from the first face to the second face and an electrically insulating polymer material coating the electrically conductive zone, at least one of the first and second faces of the interconnection film being structured so as to form a dry adhesive film, said at least one of the first and second faces having a plurality of patterns, at least part of the patterns being formed by the electrically insulating polymer material.

### TECHNICAL FIELD

The technical field of the invention is that of the electrical and mechanical interconnection of an electronic component to a substrate, for example a flexible substrate capable of deforming and adapting to a non-planar surface such as the skin. The present invention relates more particularly to an electronic structure comprising a substrate, an electronic component and an interconnection film disposed between the substrate and the electronic component.

### STATE OF THE ART

Flexible electronic structures can incorporate electronic components such as integrated circuits, sensors, actuators, batteries, passive components, radio frequency identification (RFID) chips and antennas. The manufacture of a flexible electronic structure involves transferring one or more electronic components onto a flexible substrate, also known as a flexible printed circuit. This substrate comprises a support film, for example made of polyester, polyimide, polytetrafluoroethylene or polyetheretherketone, and metal tracks disposed on the surface of the support film. Each electronic component comprises connection pads which open onto a face of the component, this face being commonly called the “active face”.

A first interconnection technique (called “wire bonding”) consists in electrically connecting the connection pads of the component to the metal tracks of the substrate by wires, when the active face of the component is facing upwards.

When, on the other hand, the active face of the component is facing downwards (in other words when it is disposed opposite the substrate), the connection pads of the component can be connected to the metal tracks of the substrate by soldering, using a fusible material, a conductive bonding agent or a conductive element pressed onto each interconnection pad. This second interconnection technique, both electrical and mechanical, is commonly referred to as “flip-chip”, in reference to the flipped position of the component. Interconnection elements, such as fusible microbeads, anisotropic conductive film or gold stud bumps, can be disposed between the component and the substrate.

As electronic components are often thick and rigid, bending stresses in the electronic structure put a lot of load on the bonding, welding or soldering interfaces, which eventually break.

To overcome this problem, it has been suggested to place the interfaces or interconnection elements as close as possible to the neutral plane of the electronic structure.

For example, patent FR1857094B1 describes a flexible electronic structure comprising a film of polymer material covered with a metal track, an electronic component, an interconnection element electrically and mechanically connecting the electronic component to the metal track and a discontinuous compensation layer to bring the neutral plane level with the interconnection element.

Moreover, document US2006/097373 describes an electronic structure comprising a flexible substrate and an electronic component bonded to the substrate by means of a layer of thermosetting resin, typically an epoxy resin. A conductive pillar electrically connects a connection pad arranged in the active face of the component and a metal track disposed on the flexible substrate. This conductive pillar extends through the thermosetting resin layer. The electronic structure further comprises a so-called passivation insulating layer, the thickness of which is chosen to bring the neutral plane of the structure level with the active face of the component.

These arrangements make it possible to limit mechanical bending stresses at the electrical connection of the component (in other words when the electronic structure is folded). On the other hand, they are not completely satisfactory when the electronic structure is subjected to tensile (stretching) or shear stresses.

### SUMMARY OF THE INVENTION

There is therefore a need to provide an electronic structure with an improved service life compared with structures of prior art, by virtue especially of improved resistance to tensile (stretching) and/or shear stresses.

According to a first aspect of the invention, this need tends to be satisfied by providing an electronic structure comprising:
a substrate;
an electronic component; and
an interconnection film disposed between the substrate and the electronic component, electrically and mechanically connecting the electronic component to the substrate.

The interconnection film comprises a first face, a second face opposite to the first face, an electrically conductive zone extending from the first face to the second face and an electrically insulating polymer material coating the electrically conductive zone, at least one of the first and second faces of the interconnection film being structured so as to form a dry adhesive film, said at least one of the first and second faces having a plurality of patterns, at least part of the patterns being formed by the electrically insulating polymer material.

In one preferred embodiment, the patterns are mushroom-shaped, each mushroom-shaped pattern comprising a pillar having a cap thereabove, the cap having, in a plane parallel to the substrate, dimensions greater than those of the pillar.

In one alternative embodiment, the patterns are pillars with a constant cross-section over their entire height or with an increasing cross-section away from a median plane of the interconnection film.

The electronic structure according to the first aspect of the invention may also have one or more of the characteristics below, considered individually or according to any technically possible combinations:
the pillar of the patterns has a height of between 5 μm and 200 μm and dimensions of between 1 μm and 100 μm in a plane parallel to the substrate;
the cap of the patterns has a height of between 1 μm and 2 μm and, in a plane parallel to the substrate, maximum dimensions equal to the dimensions of the pillar increased by a value of between 1 μm and 6 μm;
at least part of the patterns are electrically conductive and belong to the electrically conductive zone;
the patterns have a first repeat pitch in a first direction and a second repeat pitch in a second direction different from the first direction;
the substrate comprises an electrically conductive track, the electronic component comprises a connection pad and the electrically conductive zone connects the electrically conductive track to the connection pad;
the electrically conductive zone comprises carbon nanowires, carbon nanotubes, carbon black, metal particles or graphene;
the interconnection film is flexible and/or stretchable;
the interconnection film is capable of undergoing, without breaking, bending with a radius of curvature less than or equal to 1000 mm;
the interconnection film is capable of elongating under mechanical load by more than 5% without breaking;
the electrically insulating polymer material is parylene or an elastomer, for example polyurethane, polyurethane-acrylate, polyvinylsiloxane, polypropylene, polylactic-co-glycolic acid or a silicone elastomer such as polydimethylsiloxane (PDMS) or polyaddition silicone;
the electronic component is entirely covered with an encapsulation layer consisting of the electrically insulating polymer material.

A second aspect of the invention relates to a method for manufacturing an electronic structure, comprising the following steps of:
providing an interconnection film comprising a first face, a second face opposite to the first face, an electrically conductive zone extending from the first face to the second face and an electrically insulating polymer material coating the electrically conductive zone, at least one of the first and second faces of the interconnection film being structured so as to form a dry adhesive film, said at least one of the first and second faces having a plurality of patterns, at least part of the patterns being formed by the electrically insulating polymer material;
disposing the interconnection film on a substrate; and
disposing an electronic component on the interconnection film, such that the electronic component is electrically and mechanically connected to the substrate by the interconnection film.

In one preferred implementation of the manufacturing method, the step of providing the interconnection film comprises the following sub-steps of:
providing a mould comprising cavities;
depositing an electrically conductive material into a region of the mould, thus forming an electrically conductive zone;
depositing an electrically insulating polymer material into the mould so as to coat the electrically conductive zone; and
releasing the interconnection film from the mould.

### BRIEF DESCRIPTION OF THE FIGURES

Further characteristics and advantages of the invention will be more apparent from the description given below, by way of indicating and in no way limiting purposes, with reference to the following figures:

FIG. 1 schematically represents a first embodiment of an electronic structure according to the first aspect of the invention;

FIG. 2 schematically represents a second embodiment of the electronic structure;

FIG. 3 schematically represents a third embodiment of the electronic structure;

FIG. 4 represents a front view of an exemplary interconnection film belonging to the electronic structure;

FIG. 5 schematically represents a fourth embodiment of the electronic structure;

FIG. 6 schematically represents a fifth embodiment of the electronic structure;

FIGS. 7A to 7C represent steps in a method for manufacturing an electronic structure according to the second aspect of the invention; and

FIGS. 8A to 8E represent steps for manufacturing an interconnection film.

For the sake of clarity, identical or similar elements are marked by identical reference signs throughout the figures.

### DETAILED DESCRIPTION

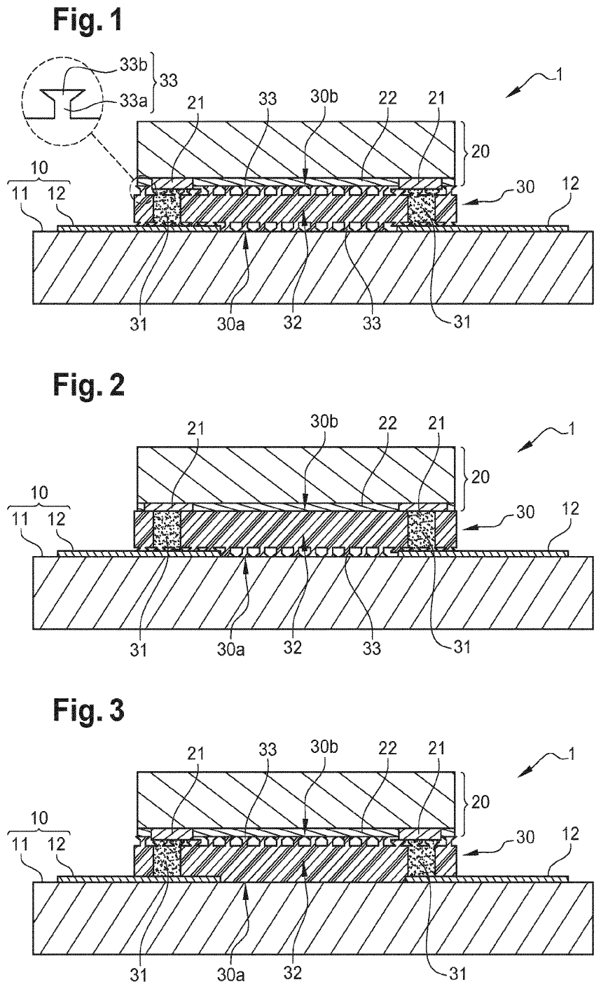

FIGS. 1 to 3, 5 and 6 represent schematic cross section views of different embodiments of an electronic structure 1.

In a manner common to all these embodiments, the electronic structure 1 comprises a substrate 10, an electronic component 20 and an interconnection film 30 disposed between the substrate 10 and the electronic component 20. In the absence of mechanical stresses, the substrate 10, the electronic component 20 and the interconnection film 30 extend along parallel planes.

Advantageously, the substrate 10 is flexible, that is it can undergo, without breaking, bending with a radius of curvature less than or equal to 1000 mm. Preferably, the substrate 10 can undergo, without breaking, bending with a radius of curvature less than or equal to 200 mm and even more preferably less than or equal to 50 mm. A flexible substrate 10 imparts flexibility to the electronic structure 1, enabling it to be positioned on a non-planar support or on a surface that deforms over time, such as a moving body. The electronic structure 1 thus finds many applications in the medical field as a patch worn by a person, for example on a wrist, arm or torso.

By way of example, the electronic structure 1 may form part of a system for measuring temperature, heart rate, blood pressure or oxygen levels, an actimetry system (measurement and analysis of movements), a system for measuring skin secretion (for example, sweat), an electrical or optical stimulation system, or a drug administration system (also known as a transdermal patch).

The electronic structure 1 itself can be described as flexible (or supple) when it is capable of bending until it has a radius of curvature less than or equal to 1000 mm (preferably less than or equal to 200 mm and even more preferably less than or equal to 50 mm or less) without suffering damage.

The substrate 10 preferably comprises a support film 11 and at least one electrically conductive track 12 disposed on the support film 11. The substrate 10 may also be referred to as a printed circuit board.

In the following description, it will be considered that the substrate 10 comprises a plurality of electrically conductive tracks 12, hereinafter referred to as electrical tracks. For the sake of simplicity, only two electrical tracks 12 have been represented in the sectional plane of FIGS. 1 to 3, 5 and 6 (this sectional plane being perpendicular to the planes of the substrate 10, the electronic component 20 and the interconnection film 30).

The support film 11 advantageously consists of a flexible material, that is a material having a Young's modulus less than or equal to 10 GPa, and preferably less than or equal to 5 GPa. The support film 11 is preferably made of a polymer material, for example a polyester such as polyethylene naphthalate (or PEN) or polyethylene terephthalate (PET), a polyimide (PI), polytetrafluoroethylene (PTFE), polyetheretherketone (PEEK), polycarbonate (PC) or polyether sulphone (PES).

The following table gives an order of magnitude for the Young's modulus E of these polymer materials.

TABLE 1

| | Polymer material | | | | | | |
|---|---|---|---|---|---|---|---|
| | PEN | PET | PI | PTFE | PEEK | PC | PES |
| Young's | 0.5-1.5 | 2.8-3.1 | 2 à 8 | 0.5 | 3 à 4 | 2-2.4 | 2.6 |
| Modulus | | | | | | | |
| (GPa) | | | | | | | |

Alternatively, the support film 11 is made of a rigid material (>50 GPa), for example glass, ceramic, silicon or metal. However, the support film 11 may have a thickness enabling the substrate 10 to meet the bending condition without breaking indicated above.

The thickness of the support film 11 is preferably between 50 μm and 250 μm when it is made of a flexible material (for example, polymer material) and less than 100 μm when it is made of a rigid material such as glass or silicon.

The electrical tracks 12 may be metallic, for example copper (Cu), silver (Ag), gold (Au), aluminium (Al), tungsten (W), nickel (Ni), platinum (Pt), titanium (Ti) or ruthenium (Ru). They can be made by depositing and etching one or more metal layers, by screen printing using a paste or ink filled with metal particles or by additive methods (material jetting, 3D printing). Each electrical track 12 may consist of a single layer or of a stack of several layers having different functions (for example, adhesion layer, diffusion barrier layer and inert finishing layer). The thickness of the electrical tracks 12 may be between 50 nm and 5 μm, and preferably between 100 nm and 2 μm.

In addition to or instead of the electrical tracks 12, the substrate 10 may comprise at least one connection pad and/or at least one conductive via (not represented in the figures). Each electrical track 12 extends on the surface of the support film 11, whereas each connection pad and each conductive via extend inside the support film 11. Unlike the connection pad (located, for example, at the end of an electrical track 12), the conductive via is a through via, that is it extends from one face to the other of the support film 11.

The electronic component 20 may be an integrated circuit (for example an application-specific integrated circuit or ASIC), a sensor (temperature, heart rate, etc.), an actuator, a stimulator, a microbattery or an RFID chip. Its thickness is advantageously less than or equal to 350 μm, preferably less than or equal to 100 μm, in order to maximise the flexibility properties of the electronic structure 1.

The electronic component 20 comprises at least one connection pad 21 opening onto a so-called active face of the component (in other words, a part of the active face is formed by the connection pad 21). The connection pad 21 is preferably coated in a dielectric layer 22. It advantageously forms a planar surface with the dielectric layer 22. The dielectric layer 22, also known as the passivation layer, consists of an electrically insulating material.

As illustrated in the figures, the electronic component 20 may comprise a plurality of distinct connection pads 21 contained in the dielectric layer 22. The connection pads 21 typically constitute the input and output terminals of the electronic component 20.

The connection pads 21 are preferably made of metal, for example copper (Cu), silver (Ag), gold (Au), aluminium (Al), an aluminium alloy of the AlSi or AlCu type, tungsten (W), nickel (Ni), platinum (Pt), titanium (Ti) or ruthenium (Ru).

The active face of the electronic component 20 faces the substrate 10. Thus, the electronic component 20 is interconnected to the substrate 10 according to a “flip-chip” type interconnection technique.

The interconnection film 30 electrically and mechanically connects the electronic component 20 to the substrate 10 and comprises a first face 30a and a second face 30b opposite to the first face 30a. The first face 30a is disposed in contact with the substrate 10, while the second face 30b is disposed in contact with the electronic component 20.

The interconnection film 30 comprises one or more electrically conductive zones 31 extending from the first face 30a to the second face 30b. At least one electrically conductive zone 31, also referred to as an electrical interconnection zone, ensures the electrical connection between the electronic component 20 and the substrate 10. More particularly, an electrical interconnection zone 31 can be arranged to electrically connect a metal track 12 of the substrate 10 to a connection pad 21 of the electronic component 20. Alternatively, an electrical interconnection zone 21 can connect a connection pad or conductive via of the substrate 10 to a connection pad 21 of the electronic component 20. Preferably, the interconnection film 30 comprises several electrical interconnection zones 31.

The interconnection film 30 further comprises an electrically insulating polymer material 32 which coats (or surrounds) the electrically conductive zones 31. The polymer material 32 thus constitutes one or more electrically insulating zones that separate the electrically conductive zones 31.

This polymer material 32 allows the interconnection film 30 to stretch, compress and/or twist. The interconnection film 30 is therefore a flexible (radius of curvature less than or equal to 1000 mm, preferably less than or equal to 200 mm and even more preferably less than or equal to 50 mm) and/or stretchable film. By “stretchable”, it is meant a film that can elongate under mechanical load by more than 5%. Preferably, the polymer material 32 represents more than 50% of the total volume of the interconnection film 30. The remaining volume of the interconnection film 30 advantageously consists of the electrically conductive zones 31.

The polymer material 32 of the interconnection film 30 is preferably a parylene or an elastomer. The elastomer material may be polyurethane, polyurethane acrylate, polyvinylsiloxane, polypropylene or polylactic-co-glycolic acid (PLGA) or a silicone elastomer such as polydimethylsiloxane (PDMS) or polyaddition silicone (also known as “platinum silicone”).

The electrically conductive zones 31 comprise an electrically conductive material, preferably chosen from carbon nanowires, carbon nanotubes, carbon black, metal particles or graphene. This electrically conductive material may be used alone or as a mixture with a polymer material, identical to or different from the polymer material 32 forming the base of the interconnection film 30.

By virtue of the interconnection film 30 consisting mainly of the polymer material 32, the electronic structure 1 has excellent resistance to mechanical stresses, in particular to tensile (stretching), bending and shear stresses.

The electronic structure 1 is further remarkable in that at least one of the first and second faces 30a-30b of the interconnection film 30 is structured so as to form a dry adhesive film. A dry adhesive, sometimes referred to as “gecko tape”, is an adhesive product inspired by the gecko's legs and whose adhesive power is based on Van der Waals forces generated by micro-structuring on the surface of a material (typically a polymer material). Thus, the interconnection film 30 has all or part of the properties of a dry adhesive. The properties of a dry adhesive are directional (or anisotropic) adhesion, strong attachment with minimal mechanical preload, easy release, self-cleaning (absence of residue left on the surface), high reusability and a non-adherent default state.

Dry adhesives are good adhesives mainly in the case of perpendicular (“pull-off”) or lateral (shear) load, but less good in the case of peeling with a high peel angle. They are also breathable adhesives (advantageous for use directly on the skin).

In the embodiments represented by FIGS. 1 to 3, 5 and 6, the structuring of the interconnection film 30 consists of a plurality of mushroom-shaped patterns 33, similar to the spatula-shaped setae of the gecko. Each mushroom-shaped pattern 33 comprises a pillar 33a (forming the foot of the mushroom) having a cap thereabove 33b (also known as a ring). The patterns 33 preferably have identical dimensions (within manufacturing tolerances).

The pillar 33a of the patterns 33 preferably extends in a direction perpendicular to the substrate 10. It has, in a plane parallel to the substrate 10, a cross section which is advantageously constant over the entire height of the pillar (cylindrical pillars) or decreasing away from the median plane of the interconnection film 30 (frustoconical pillars). This cross section is, for example, round, rectangular (especially square) or hexagonal.

The dimensions of the cross section of the pillar 33a (measured in an orthonormal reference frame) are advantageously between 1 μm and 100 μm, preferably between 5 μm and 20 μm. The height of the pillar 33a (measured perpendicularly to the plane of the substrate 10) may be between 5 μm and 200 μm, preferably between 10 μm and 100 μm.

The cap 33b of the patterns 33 is in contact with the substrate 10 or the electronic component 20 (according to whether the patterns 33 belong to the first face 30a or to the second face 30b). The cap 33b has, in a plane parallel to the substrate 10, a cross section whose dimensions are greater than those of the pillar 33a. This cross section, preferably round or oval, may be constant over the entire height of the cap or increasing away from the apex of the pillar 33a, as represented in the figures (see in particular the enlargement of FIG. 1). The maximum dimensions of the cap 33b, at its apex (that is at the distal end of the pattern 33, in contact with the substrate 10 or the electronic component 20) are preferably equal to the dimensions of the pillar 33a plus a value δ of between 1 μm and 6 μm. Thus, for example, d2=d1+δ in the case of a pillar 33a with a round cross section (diameter d1) and a cap 33b with a round cross section (diameter d2) or x2=x1+δ and y2=y1+δ in the case of a pillar 33a with a rectangular cross section (dimensions x1, y1) and a cap 33b with an oval cross section (dimensions x2, y2). The height of the cap 33b is preferably between 1 μm and 2 μm.

In one alternative embodiment not represented in the figures, the patterns 33 are pillars with a constant cross section over their entire height (cylindrical pillars) or with an increasing cross section away from the median plane of the interconnection film 30 (frustoconical pillars). The cross section of the pillars is, for example, round, rectangular (especially square) or hexagonal. The pillars preferably extend perpendicularly to the (median) plane of the interconnection film 30.

At least part of the patterns 33 are formed from electrically insulating polymer material 32 in order to ensure dry adhesion of the interconnection film 30. Other patterns 33 may instead be electrically conductive and belong to the electrically conductive zones 31. The patterns 33 improve resistance of the electrical interconnection elements to mechanical stresses, in particular tensile, shear and/or bending stresses.

In one alternative embodiment not represented by the figures, all or part of the electrically conductive zones 31 are devoid of patterns 33.

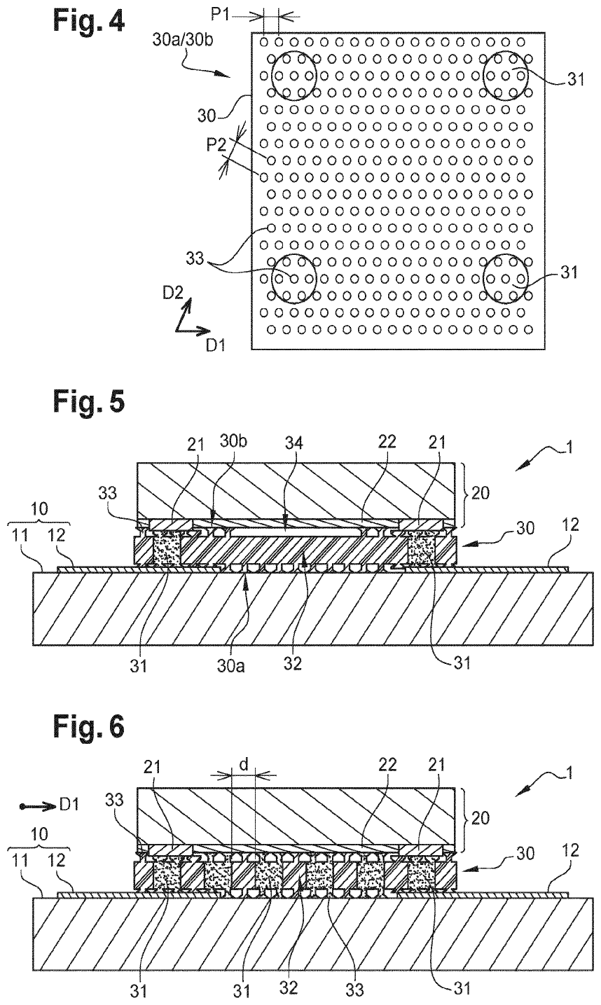

With reference to FIG. 4, the patterns 33 are preferably evenly distributed over the first face 30b and/or over the second face 30b of the interconnection film 30, in order to obtain homogeneous adhesion. They have a first repeat pitch P1 in a first direction D1 and a second repeat pitch in a second direction D2 different from the first direction. The second repeat pitch P2 may be equal to the first repeat pitch P1.

All of the patterns 33 present on one face of the interconnection film 30 thus constitute an array. The array of patterns 33 may especially have a rectangular mesh (perpendicular directions D1-D2), a square mesh (perpendicular directions D1-D2 and equal repeat pitches P1-P2) or a parallelogram shape (angle between the directions D1-D2 between 0° and 90° excluded). The array of patterns 33 may occupy all or part of the face of the interconnection film 30. It advantageously occupies more than 50%, and preferably more than 90%, of the surface area of the face of the interconnection film 30.

In the embodiment of FIG. 1, the patterns 33 are present on the first face 30a and on the second face 30b of the interconnection film 30. Thus, dry adhesion is obtained with both the substrate 10 and the electronic component 20. The interconnection film 30 preferably comprises two arrays of patterns 33. Each array of patterns 33 advantageously occupies more than 50% (preferably more than 90%) of the surface area of the first and second faces 30a-30b. Adhesive strength and resistance to mechanical stresses are then maximal.

In the embodiment of FIG. 2, the patterns 33 are present only on the first face 30a of the interconnection film 30. Thus, dry adhesion is obtained only with the substrate 10. Advantageously, the patterns 33 are arranged in an array that occupies more than 50% (preferably more than 90%) of the surface area of the first face 30a.

Conversely, in the embodiment of FIG. 3, the patterns 33 are present only on the second face 30b of the interconnection film 30. Thus, dry adhesion is obtained only with the electronic component 20. Advantageously, the patterns 33 are arranged in an array that occupies more than 50% (preferably more than 90%) of the surface area of the second face 30b.

FIG. 4 is a front view of an exemplary embodiment of the interconnection film 30, wherein the patterns 33 are arranged in an array having a parallelogram-shaped (and more precisely rhombus-shaped) mesh. The patterns 33 also have a cap with a round cross section. The distance between two consecutive patterns 33 in the array is equal to the (maximum) diameter of the cap (hence repeat pitches P1, P2 equal to twice the diameter of the cap). This exemplary embodiment of the interconnection film 30 is especially compatible with the three embodiments of the electronic structure 1 previously described (in connection with FIGS. 1 to 3).

Furthermore, the faces 30a-30b of the interconnection film 30 are rectangle-shaped in this example and the interconnection film 30 comprises four electrically conductive zones 31 disposed in proximity to the corners of the rectangle.

In the embodiment of FIG. 5, a region 34 of the second face 30b is devoid of patterns 33. This region 34 may be located opposite a sensitive zone of the electronic component 20, such as a photosensitive zone or a zone including a movable element. A region of the first face 30a may also be devoid of patterns 33.

In the embodiment of FIG. 6, the interconnection film 30 comprises a density of electrically conductive zones sufficiently high to be placed without alignment between the substrate 10 and the electronic component 20. It is then easier to assemble the electronic structure 1. Some electrically conductive zones 31 may not serve as electrical interconnection elements between the substrate 10 and the electronic component 20. The electrically conductive zones 31 may occupy up to 50% of the surface area of the first and second faces 30a-30b.

The electrically conductive zones 31 are preferably evenly spaced in at least one direction, for example the first direction D1, and even more preferably in two perpendicular directions. The distance d separating two consecutive electrically conductive zones 31 (in each direction) may be between 5 μm and 200 μm, advantageously between 30 μm and 100 μm. The interconnection film 30 is then like an anisotropic conductive film.

To avoid having to align the interconnection film 30 between the substrate 10 and the electronic component 20, the interconnection film 30 may include a matrix of conductive zones 31 (for example in the form of cylinders) the repeat pitch of which (in each direction) is less than the dimension of the connection pads 21 (in said direction).

The embodiment of FIG. 6 can be combined with any of the embodiments previously described.

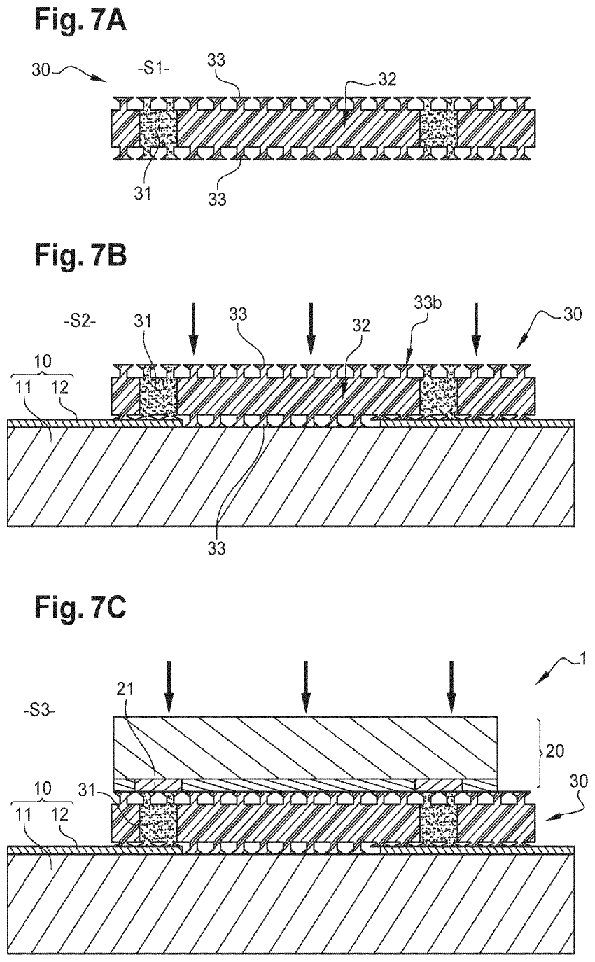

FIGS. 7A to 7C illustrate steps S1 to S3 of a method for manufacturing (or assembling) the electronic structure 1.

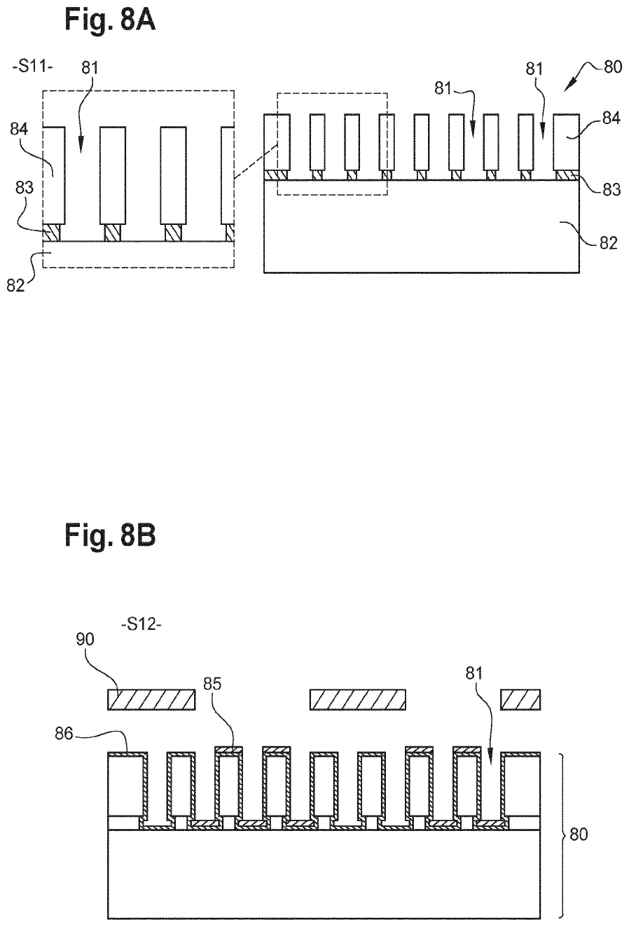

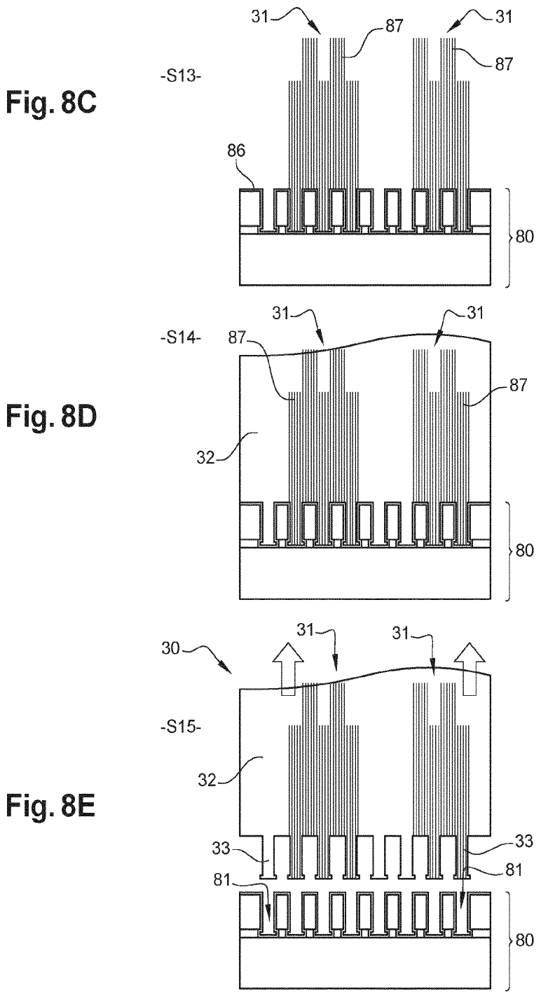

Step S1 in FIG. 7A consists in providing or manufacturing the interconnection film 30. One preferred way of manufacturing the interconnection film 30 will be described later in connection with FIGS. 8A-8E.

Then, in step S2 of FIG. 7B, the interconnection film 30 is transferred onto the substrate 10. Advantageously, pressure is applied to the second face 30b of the interconnection film 30 in order to maximise the adhesive strength with the substrate 10 (for example by maximising number of patterns 33 in contact with the substrate 10).

More particularly, the interconnection film 30 may be positioned on the substrate 10 such that at least one electrically conductive zone 31 of the interconnection film 30 contacts an electrical track 12 (a connection pad or a via) of the substrate 10.

Finally, during a so-called hybridisation step S3 represented by FIG. 7C, the electronic component 20 is transferred onto the interconnection film 30. More particularly, the electronic component 20 is positioned on the interconnection film 30 so that each connection pad 21 (each input/output terminal) of the electronic component 20 contacts an electrically conductive zone 31 of the interconnection film 30 (itself in contact with a metal track 12 of the substrate 10). Again, pressure may be exerted to the upper face of the electronic component 20 (the face opposite to the active/lower face).

Rather than applying pressures separately to the interconnection film 30 (step S2) and to the electronic component 20 (step S3), a compressive stress (perpendicular to the plane of the substrate 10) may be applied to the electronic structure 1 after the step S3 of hybridising the electronic component 20.

Finally, the method for manufacturing may comprise a step of encapsulating the electronic component 20 on the substrate 10. This encapsulation step may comprise forming a (so-called encapsulation) dielectric layer on the substrate 10 and the electronic component 20, so as to entirely cover the electronic component 20 (its upper face and its side walls). The dielectric layer may be made of ceramic or a polymer material. The encapsulation polymer material is advantageously identical to the polymer material 32 of the interconnection film 30.

FIGS. 8A to 8E represent steps S11 to S15 of a method for manufacturing the interconnection film 30.

Step S11 of FIG. 8A consists in providing a mould 80 comprising cavities 81 for forming the patterns 33 (mushroom-shaped here). The mould 80 is advantageously made from a silicon-on-insulator (SOI) substrate, for example as described in document [“Bioinspired, Highly Stretchable, and Conductive Dry Adhesives Based on 1D-2D Hybrid Carbon Nanocomposites for All-in-One ECG Electrodes”, ACS Nano 2016, 10, 4, 4770-4778]. The SOI substrate comprises a silicon support layer 82, a Buried OXide layer (or BOX layer) 83 disposed on the support layer 82 and a silicon thin film 84 disposed on the BOX layer 83.

Forming the cavities 81 in the mould 80 can thus comprise a sub-step of forming a mask on the SOI substrate, a sub-step of anisotropically etching (for example by Deep Reactive Ion Etching or DRIE) the silicon thin film 84 through the mask until it reaches the underlying BOX layer 83, a step of removing the mask, and a step of etching the silicon thin film 84 through the mask until it reaches the underlying BOX layer 83, a step of removing the mask, and finally a sub-step of isotropically etching (for example wet etching in a hydrofluoric acid bath) the BOX 83 layer selectively with respect to the support layer 82 and the silicon thin film 84. The portion of the cavities 81 located in the silicon thin film 84 is intended to form the pillar of the patterns 33, while the portion of the cavities 81 located in the BOX layer 83 is for forming the cap of the patterns 33.

An electrically conductive material is then deposited into one or more distinct regions of the mould 80, to form the electrically conductive zones 31 of the interconnection film 30. Preferably, the electrically conductive material is deposited into regions of the mould 80 provided with cavities 81.

FIGS. 8B and 8C represent, by way of example, the local growth of carbon nanotubes in the mould 80. In step S12 of FIG. 8B, a catalyst 85 is deposited into the regions of the mould 81, for example through a shadow mask 90. The catalyst 85, for example iron, can be deposited by vacuum evaporation. The deposition of the catalyst 85 may be preceded by the deposition of an alumina layer 86 onto the mould 80, for example by Atomic Layer Deposition (ALD). Then, in step S13 of FIG. 8C, carbon nanotubes 87 are grown from the catalyst 85, preferably by hot-filament assisted Chemical Vapour Deposition (CVD).

According to one alternative implementation, the electrically conductive material is a mixture of polymer material and conductive particles (metal particles, carbon black, etc.). It is deposited locally onto the mould 80, for example through a mask.

Step S14 in FIG. 8D comprises coating the electrically conductive zones 31 (here formed by carbon nanotubes 87) with the electrically insulating polymer material 32. The polymer material 32, initially in liquid form, is deposited (poured) onto the mould 81 around the electrically conductive zones 31, then cured or cross-linked (under conditions specific to each polymer material).

Finally, in step S15 of FIG. 8E, the film comprising the electrically conductive zones 31 coated with the polymer material 32 is extracted from the mould 80. It constitutes an interconnection film 30 having a single structured face (patterns 33 whose shape and dimensions correspond to the cavities 81 of the mould 80).

To obtain an interconnection film 30 whose two faces are structured, two films as represented by FIG. 8E can be manufactured and then coupled together (at their unstructured face), for example by plasma-type surface activation and then pressure assembling.

Numerous alternatives and modifications of the electronic structure and its manufacturing method will become apparent to the person skilled in the art. In particular, the substrate 10 may not be flexible. In this case, the interconnection film 30 is advantageous for absorbing mechanical stresses due to the difference in thermal expansion coefficients between the substrate 10 and the electronic component 20.

1-13. (canceled)

14. An electronic structure comprising:
a substrate comprising:
a support film; and
an electrically conductive track disposed on the support film or a connection pad extending inside the support film or a conductive via extending inside the support film;
an electronic component; and
an interconnection film disposed between the substrate and the electronic component, electrically and mechanically connecting the electronic component to the substrate, the interconnection film comprising:
a first face;
a second face opposite to the first face;
an electrically conductive zone extending from the first face to the second face and ensuring electrical connection between the electronic component and the substrate;
an electrically insulating polymer material coating the electrically conductive zone,
at least one of the first and second faces of the interconnection film being structured so as to form a dry adhesive film, said at least one of the first and second faces having a plurality of patterns, the patterns being pillars with an increasing cross section away from a median plane of the interconnection film, or mushroom-shaped patterns, each mushroom-shaped pattern comprising a pillar having a cap thereabove, the cap having, in a plane parallel to the substrate, dimensions greater than those of the pillar, a first part of the patterns being formed by the electrically insulating polymer material and a second part of the patterns being electrically conductive and belonging to the electrically conductive zone.

15. The structure according to claim 14, wherein:
the pillar of the patterns has a height of between 5 μm and 200 μm and dimensions of between 1 μm and 100 μm in a plane parallel to the substrate;
the cap of the patterns has a height of between 1 μm and 2 μm and, in a plane parallel to the substrate, maximum dimensions equal to the dimensions of the pillar increased by a value of between 1 μm and 6 μm.

16. The structure according to claim 14, wherein the patterns have a first repeat pitch in a first direction and a second repeat pitch in a second direction different from the first direction.

17. The structure according to claim 14, wherein:
the electronic component comprises a connection pad; and
the electrically conductive zone connects the electrically conductive track, the connection pad or the conductive via of the substrate to the connection pad of the electronic component.

18. The structure according to claim 14, wherein the electrically conductive zone comprises carbon nanowires, carbon nanotubes, carbon black, metal particles or graphene.

19. The structure according to claim 14, wherein the interconnection film is capable of undergoing, without breaking, bending with a radius of curvature less than or equal to 1000 mm.

20. The structure according to claim 14, wherein the interconnection film is capable of elongating under mechanical load by more than 5% without breaking.

21. The structure according to claim 14, wherein the electrically insulating polymer material is parylene or an elastomer, for example polyurethane, polyurethane acrylate, polyvinylsiloxane, polypropylene, polylactic-co-glycolic acid or a silicone elastomer such as polydimethylsiloxane (PDMS) or polyaddition silicone.

22. The structure according to claim 14, wherein the electronic component is entirely covered with an encapsulation layer consisting of the electrically insulating polymer material.

23. A method for manufacturing an electronic structure comprising:
providing an interconnection film comprising a first face, a second face opposite to the first face, an electrically conductive zone extending from the first face to the second face and an electrically insulating polymer material coating the electrically conductive zone, at least one of the first and second faces of the interconnection film being structured so as to form a dry adhesive film, said at least one of the first and second faces having a plurality of patterns, the patterns being pillars with an increasing cross section away from a median plane of the interconnection film, or mushroom-shaped patterns, each mushroom-shaped pattern comprising a pillar having a cap thereabove, the cap having, in a plane parallel to the substrate, dimensions greater than those of the pillar, a first part of the patterns being formed by the electrically insulating polymer material and a second part of the patterns being electrically conductive and belonging to the electrically conductive zone;
disposing the interconnection film on a substrate comprising a support film and an electrically conductive track disposed on the support film or a connection pad extending inside the support film or a conductive via extending inside the support film; and
disposing an electronic component on the interconnection film, so that the electronic component is electrically and mechanically connected to the substrate by the interconnection film.

24. The method according to claim 23, wherein providing the interconnection film comprises:
providing a mould comprising cavities;
depositing an electrically conductive material into a region of the mould, thus forming an electrically conductive zone;
depositing an electrically insulating polymer material into the mould so as to coat the electrically conductive zone; and
releasing the interconnection film from the mould.
